(19) United States
(12) Patent Application Publication
(10) Pub. No.: US 2008/0122111 A1
(43) Pub. Date: May 29, 2008

(54) SEMICONDUCTOR DEVICE AND FABRICATING METHOD THEREOF

(76) Inventor: Tae-Young Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/933,755

(22) Filed: Nov. 1, 2007

(30) Foreign Application Priority Data
Nov. 27, 2006 (KR) 10-2006-0117379

(51) Int. Cl. H01L 23/48; H01L 21/4763

(52) U.S. Cl. 257/774; 438/624; 257/E23.01; 257/E21.495

(57) ABSTRACT

A semiconductor device and fabricating method thereof for preventing damage to a low-k dielectric by a metal line process. The method can include sequentially forming a first etch stop layer, a first insulating layer and a second etch stop layer over a semiconductor substrate; forming a plurality of first insulating layer patterns; forming a second insulating layer in gaps between the plurality of first insulating layer patterns; and forming a damascene-type via in each one of the plurality of first insulating layer patterns.

The present application claims priority under 35 U.S.C. 119 to Korean Patent Application No. 10-2006-0117379, filed on Nov. 27, 2006, which is hereby incorporated by reference in its entirety.

### BACKGROUND

Aspects of semiconductor fabrication technology have focused on high integration and high speed semiconductor devices having at least one insulating layer for insulating conductors from each other. Such an insulating layer, however, may interfere or turns on high-speed electric signals, thereby failing to provide any insulation.

In a DC voltage of a charger, an insulating layer or dielectric can play a role in charging positive or negative charges between the two poles. However, in case that an AC voltage is applied, current leaks between the two poles.

In order to solve the problem of current leakage, many efforts have been made to research and develop a low-k dielectric as an insulating layer. In various dielectric materials, a dielectric constant can be set at 3.5˜4.5, and any dielectric material having a dielectric constant below 2.7 can be called a low-k dielectric. The low-k dielectric can be obtained by attaching a material required for growing a coarse film to a surface at a low temperature by chemical vapor deposition and stabilizing the attached material by annealing. This process can provide a film having a dielectric constant of about 2.7.

However, since the material is adsorbed without activation energy, it can be utilized for a case that a film is deposited without a gap-fill property. Namely, such a dielectric material can be used only as a film for a damascene process.

Since the low-k dielectric can have low porosity, and thus, lacks strong moisture adsorption, its reliability is degraded due to metal line corrosion caused by the adsorbed moisture, a dielectric constant increment of the low-k dielectric, etc.

Moreover, various types of structural damage can result using the low-k dielectric, such as profile failure after an etching such as reactive ion etch (RIE) and the like, bowing phenomenon attributed to lack of carbon in the low-k dielectric due to oxygen plasma gas in ashing, etc.

### SUMMARY

In accordance with embodiments, a semiconductor device and a fabricating method thereof that is suitable for a wide scope of applications, for instance, preventing damage caused to a low-k dielectric by a metal line process.

In accordance with embodiments, a semiconductor device having a normal via profile including a low-k dielectric formed in an area having no local via for an insulating interlayer formed between multi-layer metal lines.

Embodiments relate to a method of fabricating a semiconductor device including at least one of the following steps: sequentially forming a first etch stop layer, a first insulating layer and a second etch stop layer over a semiconductor substrate; forming a plurality of first insulating layer patterns; forming a second insulating layer in gaps between the plurality of first insulating layer patterns; and forming a damascene-type via in each one of the plurality of first insulating layer patterns.

Embodiments relate to a semiconductor device including a plurality of low-k dielectric patterns locally formed spaced apart over a semiconductor substrate; and a damascene type via formed in areas between the plurality of low-k dielectric patterns.

### DRAWINGS

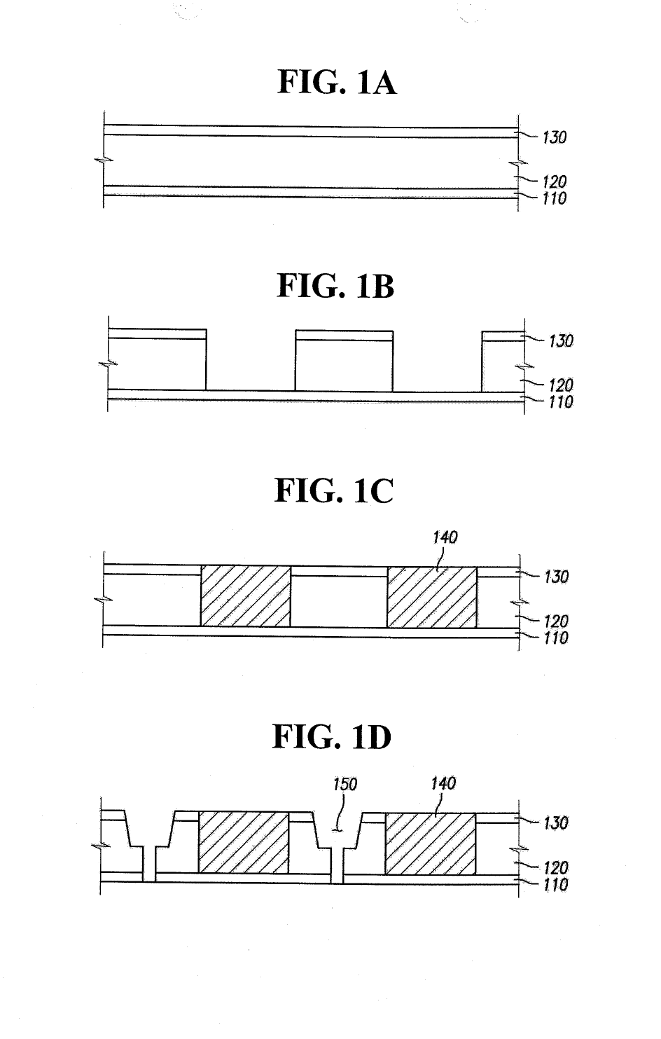

Example FIGS. 1A to 1D illustrate a method of fabricating a semiconductor device, in accordance with embodiments.

### DESCRIPTION

As illustrated in example FIG. 1A, first etch stop layer 110, first insulating layer 120 and second etch stop layer 130 can be sequentially formed on and/or over a substrate provided with a prescribed lower structure.

First etch stop layer 110 can be used for a patterning process for first insulating layer 120 and second etch stop layer 130 to form an area for the etch for via holes. First etch stop layer can be composed of a nitride film. First insulating layer 120 can be used as an inter-metal dielectric (IMD) layer. First insulating layer 120 can be composed of an oxide-based material such as fluorinated-doped silicate glass (FSG).

Second etch stop layer 130 can be used for chemical mechanical polishing (CMP) after deposition of second insulating layer 140. Second etch stop layer 130 can be composed of the same material as first etch stop layer 110, such as a nitride film.

As illustrated in example FIG. 1B, a first etch can be performed on second etch first insulating layer 120 and second etch stop layer 130 using a reactive ion etch (RIE) process to exposed the uppermost surface of first etch stop layer 110. The RIE results in the formation of a plurality of first insulating layer patterns.

Prior to performing the first etch, a photoresist can be coated on and/or over second etch stop layer 130 and patterning is then performed. Therefore, a prescribed photoresist pattern can be formed on and/or over second etch stop layer 130 by the patterning. The first etch can then be performed on first insulating layer 120 and second etch stop layer 130 using the photoresist pattern as an etch mask until the uppermost surface of first etch stop layer 110 is exposed.

As illustrated in example FIG. 1C, second insulating layer 140 having a low dielectric constant (low-k) can be formed in the gaps between the plurality of the first insulating layer patterns. Second insulating layer 140 can be locally formed of a low-k SiOC-based material using spin on polymer (SOP) coating to charge the gaps between the plurality of first insulating layer patterns.

After formation of second insulating layer 140, chemical mechanical polishing can be performed on the entire substrate on which second insulating layer 140 is formed, until the uppermost surface of second etch stop layer 130 is exposed.

As illustrated in example FIG. 1D, while the low-k insulating layer is locally formed in the IMD, damascene-type via 150 for interconnection between via holes can be formed by performing a second etch on the plurality of first insulating layer patterns. Dual damascene-type via hole may be formed in accordance with embodiments.

Because each of the first insulating layer patterns can be formed of a hard oxide-based FSG material instead of a low-k porous dielectric, it is capable of preventing poor profiled of the via after completion of a dry etch such as RIE for forming the via.

Because each via is not formed of a low-k dielectric, it is capable of reducing bowing due to the lack of carbon attributed to oxygen plasma gas in ashing and the like. Hence, process reliability can be considerably enhanced.

In accordance with embodiments, a semiconductor device having advantages can be produced. For instance, since a low-k dielectric material can be locally provided to an IMD having vias for interconnections of multi-layer lines and provides hard a oxide-based material such as FSG to an area for forming vias, thereby preventing degradation of a via profile. Embodiments may also avoid formation of vias for a low-k dielectric for reducing bowing caused by the lack of carbon attributed to oxygen plasma gas in ashing and the like, thereby enhancing process reliability.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
sequentially forming a first etch stop layer, a first insulating layer and a second etch stop layer over a semiconductor substrate;
forming a plurality of first insulating layer patterns;
forming a second insulating layer in gaps between the plurality of first insulating layer patterns; and
forming a damascene-type via in each one of the plurality of first insulating layer patterns.

2. The method of claim 1, further comprising performing chemical mechanical polishing on the semiconductor substrate to expose the uppermost surface of the second etch stop layer after forming the second insulating layer.

3. The method of claim 1, wherein the first etch stop layer and the second etch stop layer are composed of the same material.

4. The method of claim 3, wherein the first etch stop layer and the second etch stop layer comprises a nitride layer.

5. The method of claim 1, wherein the first insulating layer comprises an oxide-based material.

6. The method of claim 5, wherein the oxide-based material comprises a fluorinated silicate glass-based dielectric material.

7. The method of claim 1, wherein the second insulating layer comprises a low-k based material.

8. The method of claim 7, wherein the low-k based material comprises a SiOC-based dielectric material.

9. The method of claim 1, wherein the second insulating layer is formed using spin-on-polymer coating to charge the gaps between the plurality of first insulating layer patterns.

10. The method of claim 1, wherein forming the plurality of first insulating layer patterns is done using a first etch process on the second etch stop layer and the first insulating layer, and forming the damascene-type via is done by performing a second etch on the plurality of first insulating layer patterns.

11. The method of claim 10, wherein the first etch and the second etch is done using the same etching method.

12. The method of claim 11, wherein the first etch and the second etch is done using reactive ion etching.

13. The method of claim 12, wherein the first etch uses a prescribed photoresist pattern to expose an uppermost surface of the first etch stop layer.

14. The method of claim 1, wherein the semiconductor substrate is provided with a lower structure.

15. An apparatus comprising:
a plurality of low-k dielectric patterns locally formed spaced apart over a semiconductor substrate; and
a damascene type via formed in areas between the plurality of low-k dielectric patterns.

16. The apparatus of claim 15, wherein the damascene-type via is configured to have a dual damascene structure.

17. The apparatus of claim 16, wherein each area in which the damascene-type via is formed comprises an oxide-based material.

18. The apparatus of claim 17, wherein each area in which the damascene-type via is formed comprises a fluorinated silicate glass-based dielectric material.

19. The method of claim 15, wherein the plurality of low-k dielectric patterns comprises a SiOC-based dielectric material.
